(19) United States
(12) Patent Application Publication
(10) Pub. No.: US 2010/0206073 A1
(43) Pub. Date: Aug. 19, 2010

(54) ANGULAR VELOCITY DETECTING DEVICE AND MANUFACTURING METHOD OF THE SAME

(75) Inventors: Daisuke Kaminishi, Kyoto-fu (JP); Masaki Takaoka, Kyoto-fu (JP); Yoshikazu Fujimori, Kyoto-fu (JP)

Correspondence Address: FISH & RICHARDSON P.C., P.O. BOX 1022, MINNEAPOLIS, MN, 55440-1022, US

(73) Assignee: Rohm Co., Ltd, Kyoyo-fu (JP)

(21) Appl. No.: 12/678,942

(22) PCT Filed: Sep. 25, 2008
(86) PCT No.: PCT/JP2008/067301

§ 371 Date: Mar. 18, 2010

(30) Foreign Application Priority Data
Sep. 25, 2007 (EP) 2007-246787
Sep. 25, 2007 (EP) 2007-247885

(51) Int. Cl. G01C 19/56; H01L 21/02

(52) U.S. Cl. 73/504.12; 438/50; 257/E21.002

(57) ABSTRACT

An angular velocity detecting device includes a semiconductor substrate (2); an oscillator (3) formed on the semiconductor substrate (2); and a control circuit (4) which is formed on the semiconductor substrate (2) and controls the oscillator (3).

### TECHNICAL FIELD

The present invention relates to an angular velocity detecting device including an oscillator having a piezoelectric film and a method of manufacturing the angular velocity detecting device.

### BACKGROUND ART

There are known angular velocity detecting devices which have a micro electro-mechanical system (MEMS) structure and include a beam-type oscillator having a piezoelectric film and methods for manufacturing the angular velocity detecting devices. Patent Citation 1 discloses an angular velocity detecting device which includes an IC substrate and a gyro sensor element having a silicon substrate and an oscillator. A part of the oscillator is obtained by etching the silicon substrate. The oscillator includes a lower electrode, a piezoelectric film, and an upper electrode which are sequentially layered. The IC substrate includes an IC circuit which is connected to the upper and lower electrodes and controls the oscillator.

In this angular velocity detecting device, when angular velocity is applied to the oscillator vibrating in a predetermined direction by a drive signal from the IC substrate, the Coriolis force acts on the oscillator. Based on vibration due to the Coriolis force and vibration due to the drive signal, a vibration signal is outputted from the piezoelectric film of the oscillator through the upper electrode. The vibration signal is inputted into a control circuit and is then converted into an output signal based on the angular velocity to detect the angular velocity.
[Patent Citation 1] Japanese Patent Laid-open Publication No. 2005-227110

### DISCLOSURE OF INVENTION

### Technical Problem

However, in the angular velocity detecting device described above, the oscillator and the IC substrate having the IC circuit controlling the oscillator are composed of different components. Accordingly, it is difficult to reduce the thickness of the angular velocity detecting device to 1 mm or less. The angular velocity detecting device is therefore difficult to miniaturize.

In the light of the aforementioned problem, an object of the present invention is to provide an angular velocity detecting device capable of being miniaturized and a method of manufacturing the angular velocity detecting device.

### Technical Solution

According to an aspect of the present invention, provided is an angular velocity detecting device, which includes: a semiconductor substrate; an oscillator formed on the semiconductor substrate; and a control circuit which is formed on the semiconductor substrate and controls the oscillator.

According to another aspect of the present invention, provided is a method of manufacturing an angular velocity detecting device including an oscillator having a plurality of beam-type electrodes, which includes: stacking a lower protective film, a lower electrode, a piezoelectric film, an upper electrode film, and a mask material on a semiconductor substrate; patterning the mask material; and etching the lower protective film, lower electrode, piezoelectric film, and upper electrode film of the oscillator at a same time.

### Advantageous Effects

According to the present invention, it is possible to provide an angular velocity detecting device which can be miniaturized and a method of manufacturing the angular velocity detecting device.

### BRIEF DESCRIPTION OF DRAWINGS

FIG. 1 is an entire configuration view of an angular velocity detecting device according to a first embodiment of the present invention.

FIG. 2 is a cross-sectional view taken along a direction II-II of FIG. 1.

FIG. 3 is a perspective view of an oscillator shown in FIG. 1.

FIG. 4 is a cross-sectional process view for explaining a method of manufacturing the angular velocity detecting device according to the first embodiment of the present invention (No. 1).

FIG. 5 is a cross-sectional process view for explaining the method of manufacturing the angular velocity detecting device according to the first embodiment of the present invention (No. 2).

FIG. 6 is a cross-sectional process view for explaining the method of manufacturing the angular velocity detecting device according to the first embodiment of the present invention (No. 3).

FIG. 7 is a cross-sectional process view for explaining the method of manufacturing the angular velocity detecting device according to the first embodiment of the present invention (No. 4).

FIG. 8 is an entire configuration view of an angular velocity detecting device according to a second embodiment of the present invention.

FIG. 9 is a schematic top view showing a configuration of an oscillator of an angular velocity detecting device according to a third embodiment of the present invention.

FIG. 10 is a cross-sectional view of the oscillator shown in FIG. 9 taken along a direction X-X.

FIG. 11 is a cross-sectional view of the oscillator shown in FIG. 9 taken along a direction XI-XI.

FIG. 12 is a schematic view showing a configuration of an angular velocity detecting device according to the third embodiment of the present invention.

FIG. 13 is a cross-sectional view of an oscillator for explaining an etching amount of a piezoelectric film according to the third embodiment of the present invention.

FIG. 14 is a graph for explaining the etching amount of the piezoelectric film according to the third embodiment of the present invention.

FIG. 15 is a table describing etch rates of materials.

FIG. 16 is a cross-sectional process view for explaining a method of manufacturing the angular velocity detecting device according to the third embodiment of the present invention (No. 1).

FIG. 17 is a cross-sectional process view for explaining the method of manufacturing the angular velocity detecting device according to the third embodiment of the present invention (No. 2).

FIG. 18 is a cross-sectional process view for explaining the method of manufacturing the angular velocity detecting device according to the third embodiment of the present invention (No. 3).

FIG. 19 is a cross-sectional process view for explaining the method of manufacturing the angular velocity detecting device according to the third embodiment of the present invention (No. 4).

FIG. 20 is a cross-sectional process view for explaining the method of manufacturing the angular velocity detecting device according to the third embodiment of the present invention (No. 5).

FIG. 21 is a cross-sectional process view for explaining the method of manufacturing the angular velocity detecting device according to the third embodiment of the present invention (No. 6).

FIG. 22 is a cross-sectional process view for explaining the method of manufacturing the angular velocity detecting device according to the third embodiment of the present invention (No. 7).

FIG. 23 is a cross-sectional process view for explaining another example of the method of manufacturing the angular velocity detecting device according to the third embodiment of the present invention (No. 1).

FIG. 24 is a cross-sectional process view for explaining the another example of the method of manufacturing the angular velocity detecting device according to the third embodiment of the present invention (No. 2).

### BEST MODE FOR CARRYING OUT THE INVENTION

Next, first to third embodiments of the present invention are described with reference to the drawings. In the following description of the drawings, same or similar portions are given same or similar referential numerals or symbols. The drawings are schematic, and the relations between thicknesses and planar dimensions, the proportion of thicknesses of layers, and the like are different from the actual ones. Specific thicknesses and dimensions should be determined referring to the following description. Moreover, it is obvious that some portions have dimensional relations and proportions different in the drawings.

Moreover, the first to third embodiment shown below show examples of devices and methods embodying the technical idea of the present invention, and the technical idea of the present invention is not specified to the following materials, shapes, structures, arrangements, and the like of constituent components. Various modifications can be added to the technical idea of the present invention within the scope of the claims.

### First Embodiment

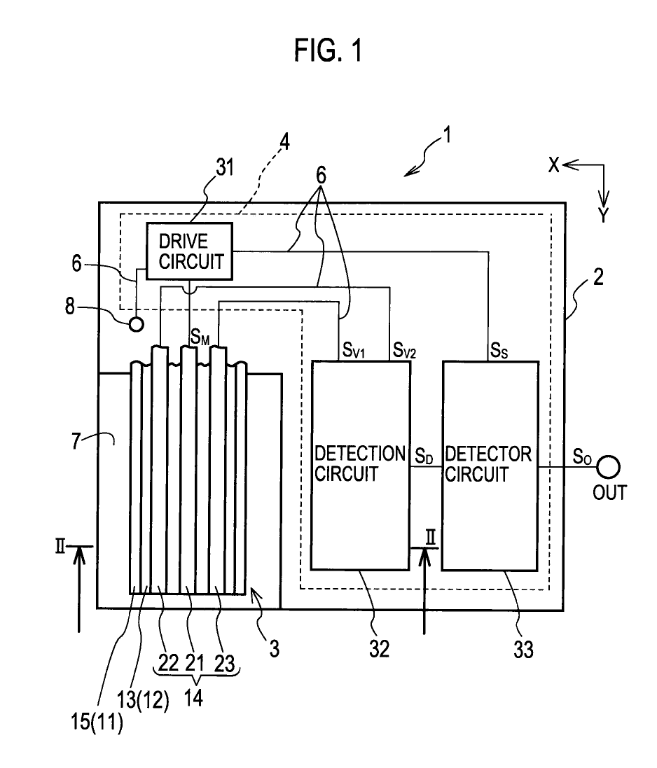

As shown in FIG. 1, an angular velocity detecting device (a gyro sensor) 1 according to the first embodiment of the present invention includes: a semiconductor substrate 2; an oscillator 3 formed on the semiconductor substrate 2; and a control circuit 4 which is formed on the semiconductor substrate 2 and controls the oscillator 3. The oscillator 3 and control circuit 4 are connected to each other through a plurality of wires 6 composed of aluminum (Al) or the like.

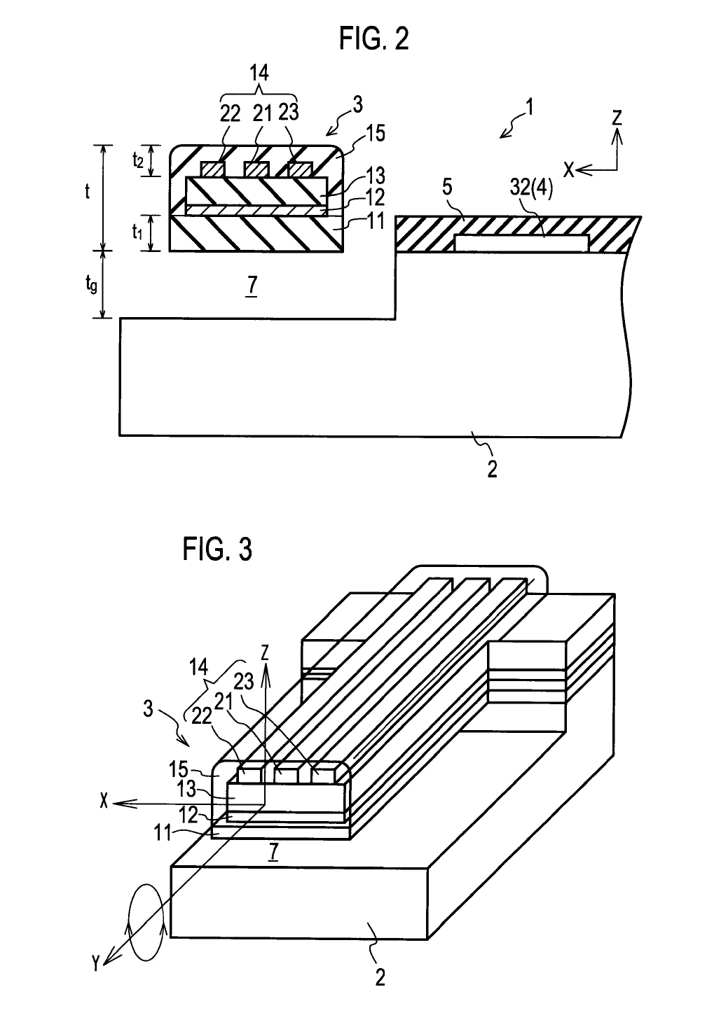

As shown in FIG. 2, the control circuit 4 is protected by a protective film 5. FIG. 2 is a cross-sectional view taken along a direction II-II of FIG. 1. The protective film 5 is an silicon oxide (SiO₂) film and is formed so as to cover the upper surface of the semiconductor substrate 2 and control circuit 4. A lower protective film 11 of the oscillator 3 and the protective film 5 are continuously formed.

FIG. 3 is a perspective view of the oscillator 3. X, Y, and Z shown by arrows in FIG. 3 indicate X, Y, and Z directions.

The semiconductor substrate 2 is a silicon (Si) substrate having a thickness of about 300 μm. The thickness of the semiconductor substrate 2 only needs to be large enough for the semiconductor substrate 2 to be held at mounting and the like and can be properly changed. In a planar view, the semiconductor 2 has a length of about 4.0 mm in the X direction and a length of about 4.5 mm in the Y direction. A part of the semiconductor substrate 2 under the oscillator 3 is etched to a depth of about 50 μm. This forms a cavity 7 with a height tg of about 50 μm between the semiconductor substrate 2 and the lower surface of the oscillator 3. The height tg of the cavity 7, which is not particularly limited, only needs to be large enough for the oscillator 3 not to be influenced by changes in air pressure caused between the oscillator 3 and semiconductor substrate 2 while the oscillator 3 is vibrating.

The oscillator 3 is formed as a beam capable of vibrating in the X-Z direction. The oscillator 3 is formed on the substrate 2. The oscillator 3 has a thickness t of about 2 to 6 μm in the Z direction and a width of about 5 to 6 μm in the X direction. The thickness t of the oscillator 3 is properly changed depending on a desired resonant frequency f in the Z direction. To increase the output sensitivity, it is preferable that the thickness t and the width of the oscillator 3 are equal to each other so that the cross-sectional shape thereof is square.

As shown in FIG. 2, the oscillator 3 includes the lower protective film 11, a lower electrode 12, a piezoelectric film 13, an upper electrode 14, and an upper protective film 15.

The lower protective film 11 is configured to protect the lower surface of the lower electrode 12 and adjust the resonant frequency f. The lower protective film 11 is formed on the lower surface of the lower electrode 12. Between the lower surface of the lower protective film 11 and the semiconductor substrate 2, the cavity 7 with a predetermined height tg (for example, 50 μm) is formed. The height tg is not particularly limited and can be properly changed depending on the amplitude of the oscillator 3 in the Z direction. The lower protective film 11 is an SiO₂ film having a thickness t1 of about 1 to 4 μm. By setting the thickness t1 of the lower protective film 11 based on Table 1 below, the resonant frequency f of the oscillator 3 is roughly adjusted. The concrete relationship between the lower protective film 11 and the resonant frequency f is shown in Table 1.

TABLE 1

| Thickness t1 of lower | |
|---|---|
| protective film (μm) | Resonant frequency f (kHz) |
| 1 | 6 |
| 2 | 9.4 |
| 3 | 13.3 |
| 3.5 | 14.7 |
| 4 | 17.1 |

The lower electrode 12 is made of platinum (Pt) with a thickness of about 200 nm and is formed so as to cover the lower surface of the piezoelectric film 13. The lower electrode 12 is connected to a drive circuit 31 through one of the wires 6 within a via hole 8.

The piezoelectric film 13 changes in voltage based on angular velocity of rotational motion of the oscillator 3 around the Y axis. The piezoelectric film is a piezoelectric zirconate titanate (PZT) film having a thickness of about 1 μm and is formed so as to cover the upper surface of the lower electrode 12.

The upper electrode 14 is composed of an iridium oxide (IrO₂)/iridium (Ir) layered film with a thickness of about 200 nm. The upper electrode 14 is formed on the upper surface of the piezoelectric film 13 so as to extend in the Y direction. The upper electrode 14 includes a drive electrode 21 and a pair of detection electrodes 22 and 23. The drive electrode 21 is connected to the drive circuit 31 through one of the wires 6. The drive electrode 21 receives from the control circuit 4, a drive signal S_{M} to vibrate the oscillator 3 in the Z direction. The detection electrodes 22 and 23 are formed at positions opposite to each other across the drive electrode 21. The detection electrodes 22 and 23 are connected to the detection circuit 32 through some of the wires 6. The detection electrodes 22 and 23 respectively output to the control circuit 4, vibration signals S_{V1} and S_{V2} containing changes in voltage of the piezoelectric film due to the angular velocity generated when the oscillator 3 rotates around the Y axis.

The upper protective film 15 protects the lower electrode 12, piezoelectric film 13, and upper electrode 14. The upper protective film 15 is formed so as to cover the side surfaces of the lower electrode 12, the upper and side surfaces of the piezoelectric film 13, and the upper surface of the upper electrode 14. The upper protective film 15 is a SiO₂ film having a thickness t2 of about 0.5 to 1.0 μm. By adjusting the thickness t2 of the upper protective film 15, the resonant frequency f is finely tuned.

The control circuit 4 controls the oscillator 3. The control circuit 4 is formed on the semiconductor substrate 2 monolithically with the oscillator 3. The control circuit 4 includes the drive circuit 31, the detection circuit 32, and a detector circuit 33.

The drive circuit 31 outputs the drive signal S_{M} to the drive electrode 21 to vibrate the oscillator 3 at a predetermined resonant frequency f in the Z direction. The drive circuit 31 outputs a synchronizing signal S_{S} to the detector circuit 33. The detection circuit 32 detects the detection signal S_{D} based on the angular velocity of the oscillator 3 from the vibration signals S_{V1} and S_{V2} based on the vibration of the oscillator 3 outputted from the detection electrodes 22 and 23 of the oscillator 3, and the detection circuit 32 outputs the detection signal S_{D} to the detector circuit 33. The detector circuit 33 detects the detection signal S_{D} inputted from the detection circuit 32. Moreover, the detector circuit 33 synchronizes the detected signal with the synchronizing signal S_{S} inputted from the drive circuit 31 and outputs an output signal S_{O} based on the angular velocity acting on the oscillator 3. The drive circuit 31, detection circuit 32, and detector circuit are composed of transistors and the like monolithically formed on the semiconductor substrate 2.

Next, the operation of the aforementioned angular velocity detecting device 1 is described.

First, the drive signal S_{M} of about 5 V is inputted from the drive circuit 31 to the drive electrode 21. The oscillator 3 therefore vibrates in the Z direction. By the vibration of the oscillator 3, the vibration signals S_{V1} and S_{V2} having polarities opposite to each other are outputted from the detection electrodes 22 and 23 to the detection circuit 32, respectively. Herein, when the oscillator 3 is rotated around the Y axis by an external force, the oscillator 3 including the piezoelectric film 13 vibrates also in the X direction. This causes the piezoelectric film 13 vibrating in the X direction to change in voltage due to the angular velocity of the rotational motion. Accordingly, the vibration signals S_{V1} and S_{V2} outputted from the detection electrodes 22 and contain the change in voltage due to the angular velocity.

The detection circuit 32 calculates a difference between the vibration signals S_{V1} and S_{V2} having polarities opposite to each other to output the drive signal S_{D} which does not contain a signal based on the vibration of the oscillator 3 in the Z direction by the drive signal S_{M}. In the detector circuit 33, the signal from the drive circuit 31 is synchronized with the angular velocity signal to detect the detection signal S_{D}. The output signal S_{O} due to the angular velocity acting on the oscillator 3 is thus outputted, and the angular velocity is thus detected.

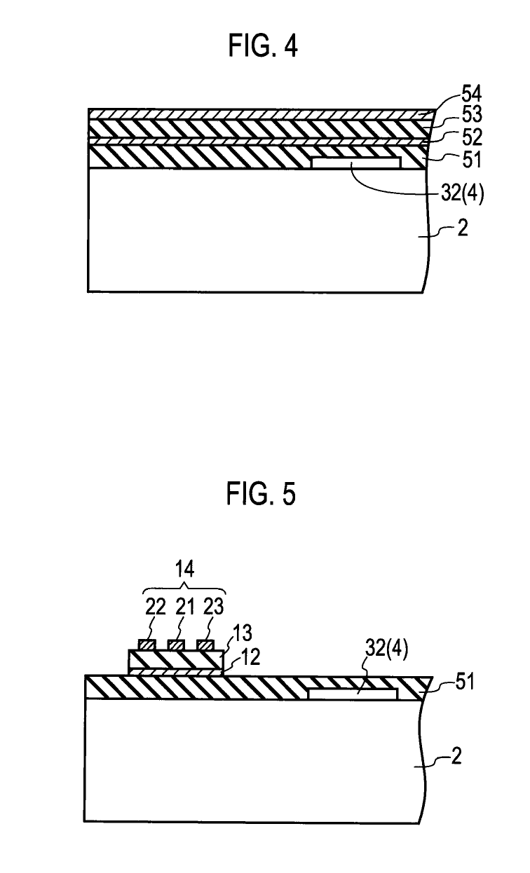

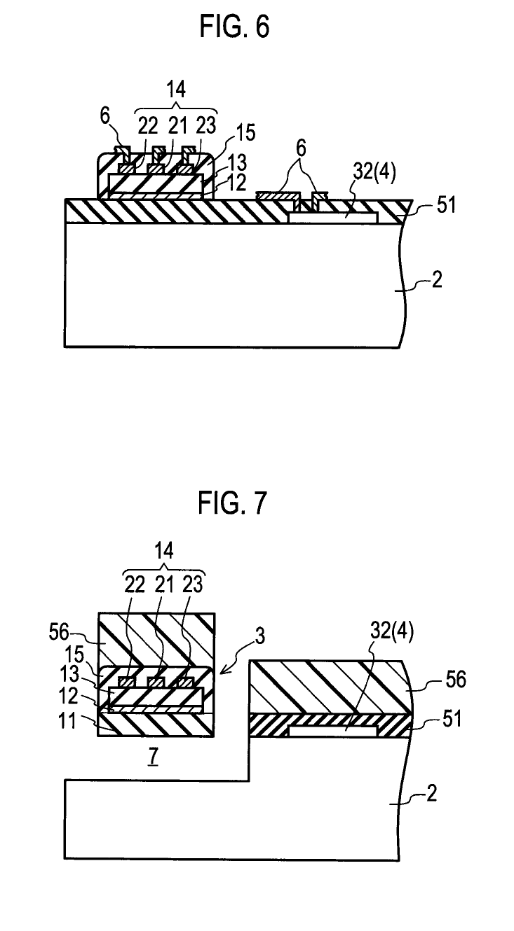

Next, a method of manufacturing the aforementioned angular velocity detecting device 1 is described. FIGS. 4 to 7 are cross-sectional views at manufacturing steps of the angular velocity detecting device. FIG. 6 is, unlike the other drawings, a cross-sectional view of a place where the wires 6 are formed.

First, as shown in FIG. 4, the control circuit 4 including the drive circuit 31, detection circuit 32, and detector circuit 33 is formed on the semiconductor substrate 2 by a known semiconductor manufacturing technique. Thereafter, an insulating film 51 composed of SiO₂ to be formed into the protective film 5 and lower protective film 11 is formed by CVD process or the like so as to cover the semiconductor substrate 2 and control circuit 4.

Next, a Pt film 52 for the lower electrode 12 is formed by sputtering. Thereafter, a PZT film 53 for the piezoelectric film 13 is formed on the Pt film 52 by a sol-gel process. Furthermore, an IrO₂ film 54 for the upper electrode 14 is formed on the PZT film 53 by sputtering.

Next, as shown in FIG. 5, after a resist film (not shown) is formed, the IrO₂/Ir film 54 is dry-etched with Ar gas and halogen gas such as chlorine (Cl₂) gas to form the upper electrode 14. After a new resist film (not shown) is formed, the PZT film 53 is dry-etched with fluorine and Ar gases to form the piezoelectric film 13. Next, the Pt film 52 is dry-etched with Ar gas and halogen gas such as chlorine (Cl₂) gas to form the lower electrode 12.

Next, an insulating film composed of a SiO₂ film is formed on the upper surface by a CVD process. As shown in FIG. 6, the insulating film is patterned by photolithography and dry etching with fluorine gas such as SF₆ to form the upper protective film 15. The wires 6 connecting the individual electrodes 21 to 23 with the control circuit 4 are formed.

Next, as shown in FIG. 7, the insulating film 51 is dry-etched with fluorine gas such as SF₆ to pattern the protective film 5 covering the lower protective film 11 and control circuit 4. A part of the semiconductor substrate 2 made of silicon is isotropically dry-etched with fluorine gas such as SF₆ to form the cavity 7 under the oscillator 3. Herein, by employing dry etching, unlike the case of wet etching, the side surfaces of the piezoelectric film 13 are prevented from being exposed. This prevents the piezoelectric film 13 from being etched.

The angular velocity detecting device 1 is thus completed.

In the angular velocity detecting device 1 according to the first embodiment, as described above, the control circuit 4 is monolithically formed on the semiconductor substrate 2 where the oscillator 3 is formed. Accordingly, the thickness of the angular velocity detecting device 1 can be made small. Moreover, the longitudinal and transverse dimensions of the angular velocity detecting device 1 in a planer view can be made small, thus achieving miniaturization of the angular velocity detecting device 1. Specifically, it is possible to realize a thickness of not more than 1 mm that allows the angular velocity detecting device 1 to be mounted on mobile phones and the like.

Moreover, by integrally forming the oscillator 3 and control circuit 4 on the semiconductor substrate 2, it is possible to omit processes of bonding, adjustment, and the like of an oscillator and a control circuit which are necessary when the oscillator and control circuit are composed of different components.

If the oscillator constitutes a single component alone, a holder to hold the oscillator is necessary, thus increasing the size of the oscillator. However, by integrally forming the oscillator 3 and control circuit 4, it is possible to easily hold the oscillator 3 without forming a holder or the like, thus preventing damage of the oscillator 3.

Moreover, the insulating film 51 and semiconductor substrate 2 are patterned by dry etching to form the cavity 7 under the oscillator 3. This can prevent exposure of the side surfaces of the piezoelectric film 13. It is therefore possible to prevent the piezoelectric film 13 from being etched and further prevent the piezoelectric film 13 from being physically damaged in use.

Furthermore, by covering the upper and lower surfaces of the oscillator 3 with the lower and upper protective films 11 and 15, the resonant frequency f of the oscillator 3 can be easily set to a desired frequency using the thicknesses t1 and t2 of the lower and upper protective films 11 and 15.

The materials constituting the angular velocity detecting device 1 can be properly changed. Specifically, the protective films may be composed of insulating films (polysilicon, SiN, or the like) other than the SiO₂ films. Moreover, the semiconductor substrate 2 may be a substrate composed of a semiconductor other than silicon.

Furthermore, in the above described example, the oscillator 3 is vibrated in the Z direction by the drive circuit 31. However, the oscillator 3 may be vibrated by the drive circuit 31 in the X direction.

### Second Embodiment

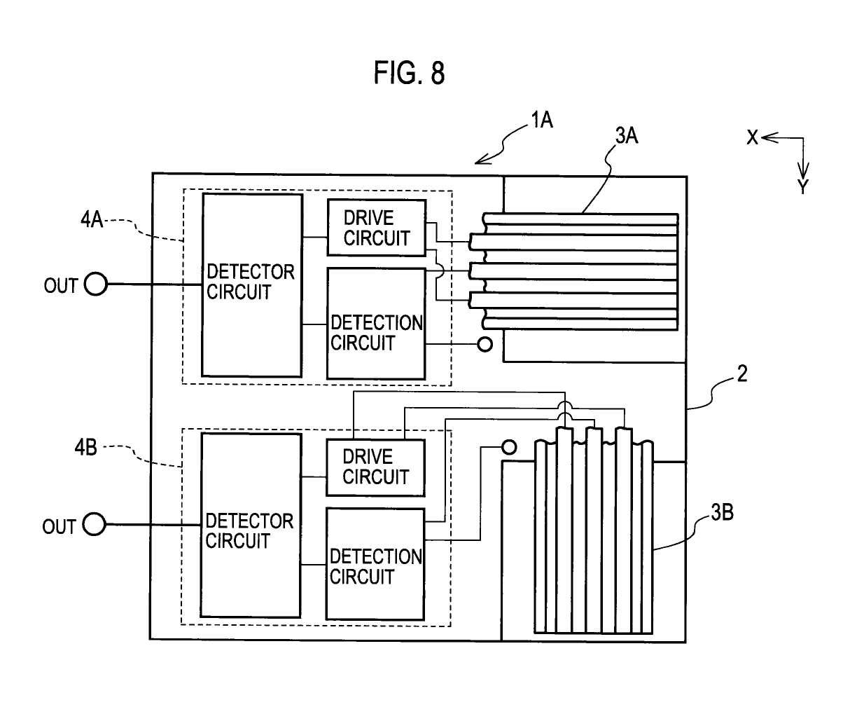

Next, the second embodiment in which the present invention is applied to a biaxial angular velocity detecting device is described with reference to the drawings. FIG. 8 is an entire configuration view of the angular velocity detecting device according to the second embodiment. Same components as those of the first embodiment are given same referential numerals, and the description thereof is omitted. X and Y shown in FIG. 8 indicate the X and Y directions, respectively, and the direction vertical to the paper surface is the Z direction.

As shown in FIG. 8, an angular velocity detecting device 1A according to the second embodiment includes the semiconductor substrate 2, a first oscillator 3A, a second oscillator 3B, a first control circuit 4A, and a second control circuit 4B.

The first oscillator 3A is formed on the semiconductor substrate 2 so as to extend in the X direction. The second oscillator 3B is formed on the semiconductor substrate 2 so as to extend in the Y direction. In other words, the first and second oscillators 3A and 3B are formed so as to extend in the directions orthogonal to each other. The first and second oscillators 3A and 3B then detect angular velocities in the directions orthogonal to each other. Specifically, the oscillator 3A detects the angular velocity around the X axis, and the oscillator 3B detects the angular velocity around the Y axis. Each of the oscillators 3A and 3B has the same configuration as that of the oscillator 3 of the first embodiment.

The first control circuit 4A controls the first oscillator 3A to detect angular velocity around the X axis. The second control circuit 4B controls the second oscillator 3B to detect angular velocity around the Y axis. The control circuits 4A and 4B are formed monolithically on the semiconductor substrate 2. Each of the control circuits 4A and 4B has the same configuration as that of the control circuit 4 of the first embodiment.

By including the two oscillators 3A and 3B, the angular velocity detecting device 1A shown in FIG. 8, as described above, can detect angular velocities around the rotational axes extending in two different directions. If the oscillators 3A and 3B are formed on the semiconductor substrate 2 using a semiconductor manufacturing technique with high accuracy such as photolithography and dry etching, the accuracy in alignment of the oscillators 3A and 3B can be increased.

Moreover, the two oscillators 3A and 3B are simultaneously formed. Accordingly, the biaxial angular velocity detecting device 1A can be easily manufactured. Furthermore, the two control circuits 4A and 4B can be simultaneously formed, and the biaxial angular velocity detecting device 1A can be therefore easily manufactured.

The above described example is the angular velocity detecting device including two oscillators. However, the present invention may be applied to an angular velocity detecting device including three or more oscillators.

### Third Embodiment

As shown in the first and second embodiments, the piezoelectric material is provided on the semiconductor substrate 2 in a form of thin film. This can increase the processing accuracy of the piezoelectric material. However, as the oscillator 3 gets smaller and thinner, the symmetry of the shape of the oscillator 3 has a greater influence on the performance of the angular velocity detecting device 1. For example, if an oscillator has an asymmetric shape in a direction of vibration generated by the Coriolis force (in a detection direction), vibration in the detection direction will occur before the angular velocity is applied. This vibration is called “abnormal vibration”. In other words, the output of the oscillator becomes very small because of the miniaturization, and the abnormal vibration generated particularly in the detection direction because of the asymmetry of the oscillator prevents accurate detection of minute changes due to the Coriolis force.

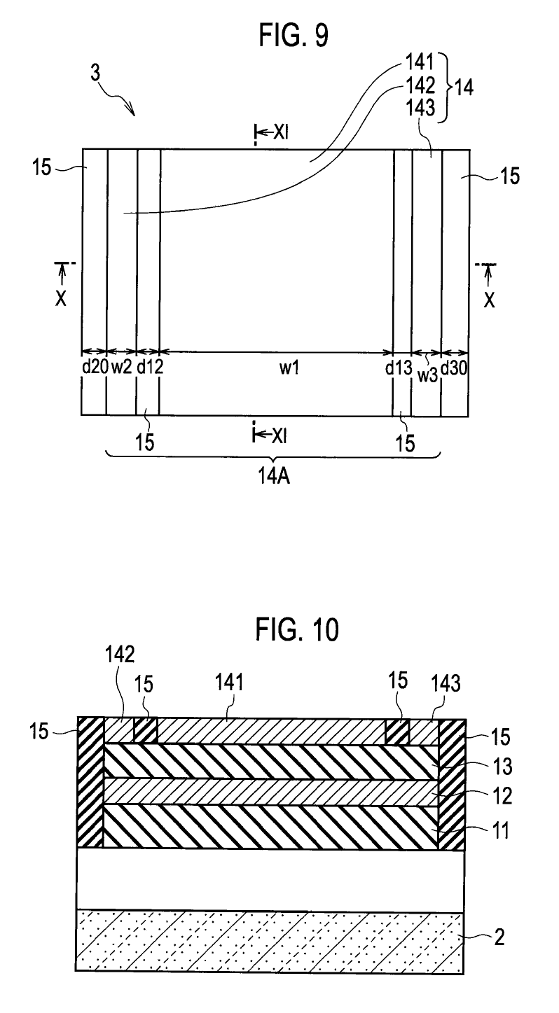

As described below, in the angular velocity detecting device according to the third embodiment, the abnormal vibration due to the asymmetric shape of the oscillator can be reduced. As shown in FIGS. 9 and 10, the angular velocity detecting device according to the third embodiment of the present invention includes an oscillator 3 having first, second, and third beam-type electrodes 141, 142, and 143 which extend in a same direction. FIG. 10 is a cross-sectional view taken along a direction X-X of FIG. 9.

A method of manufacturing the oscillator 3 shown in FIGS. 9 and 10 includes: a step of stacking the lower protective film 11, the lower electrode 12, the piezoelectric film 13, an upper electrode film, and a mask material on the semiconductor substrate 2 in this order; a step of patterning the mask material with a power supply pattern in which an interval d12 between the first and second beam-type electrodes 141 and 142 and an interval d13 between the first and third beam-type electrodes 141 and 143 are provided within an interval where the piezoelectric film 13 is not completely etched in the thickness direction by dry etching; and a step of simultaneously etching the upper electrode film, piezoelectric film 13, lower electrode 12, and lower protective film 11 on the outside of the oscillator 3 and portions of the upper electrode film between the first and second beam-type electrodes 141 and 142 and between the first and third beam-type electrodes 141 and 143 by one dry etching using the patterned mask material as a mask.

By dry etching the upper electrode film according to the power supply pattern, an electrode area 14A including the first to third beam-type electrodes 141 to 143 is formed. The electrode area 14A includes an area expanding from the outside of the second beam-type electrode 142 to the outside of the third beam-type electrode 143 across the first beam-type electrode 141. Herein, the sides of the second and third beam-type electrodes 142 and 143 facing the first beam-type electrode 141 are referred to as insides, and the sides thereof opposite to the insides are referred to as outsides. By continuously etching the lower protective film 11, lower electrode 12, piezoelectric film 13, and upper electrode film on the outside of the electrode area 14A by one dry etching, end faces of the lower protective film 11, lower electrode 12, piezoelectric film 13 are aligned with outside faces of the second and third beam-type electrodes 142 and 143.

Moreover, the intervals d12 and d13 are provided in the interval where the piezoelectric film 13 is not completely etched in the thickness direction by dry etching. Accordingly, between the first and second beam-type electrodes 141 and 142 and between the first and third beam-type electrodes 141 and 143, only the upper electrode film is completely etched, and the piezoelectric film 13 remains. The interval where the piezoelectric film 13 is not completely etched in the thickness direction by dry etching is described in detail later.

For the first to third beam-type electrodes 141 to 143 are formed by one dry etching, there is no misalignment of mask patterns caused when the electrode area 14A is formed using a plurality of etching masks. Accordingly, the oscillator 3 will not have asymmetric shape, and width W2 of the second beam-type electrode 142 and width W3 of the third beam-type electrode 143 can be made equal to each other as designed. Moreover, the intervals d12 and d13 can be made equal to each other.

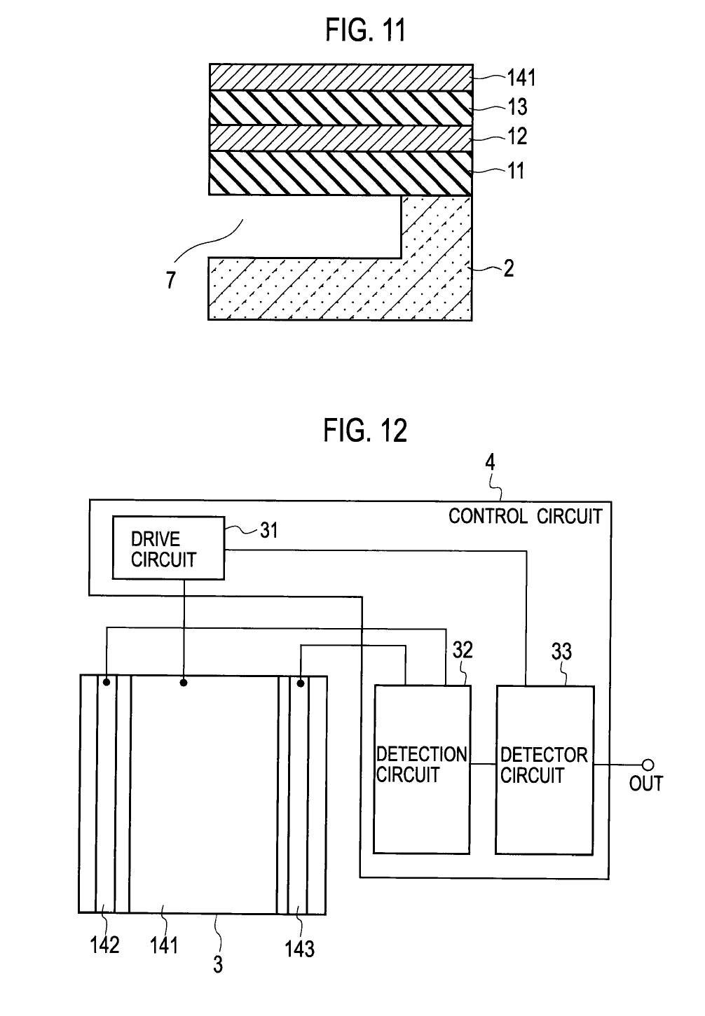

FIG. 11 is a cross-sectional view taken along a direction XI-XI of FIG. 9. As shown in FIG. 11, in the oscillator 3 of the angular velocity detecting device according to the third embodiment of the present invention, part of the semiconductor substrate 2 under the lower protective film 11 is removed to form the cavity 7. In other words, the oscillator 3 is a cantilever-type oscillator with an end of each of the first to third beam-type electrodes 141 to 143 being supported. The height of the cavity 7, or the distance between the lower surface of the lower protective film 11 and the upper surface of the semiconductor substrate 2 is about 50 μm, for example.

The angular velocity detecting device shown in FIGS. 9 to 11 is an angular velocity detecting device in which the drive electrode of the oscillator 3 is vibrated in a certain direction (a drive direction) at a predetermined frequency (drive vibration) and the detection electrode detect vibration generated at the drive electrode in a direction perpendicular to the drive vibration due to the Coriolis force generated by addition of angular velocity, so as to calculate the angular velocity.

For example, while the first beam-type electrode 141 as the drive electrode is vibrating in the vertical direction, the horizontal motion of the first beam-type electrode 141 generated by the Coriolis force is detected by the second and third beam-type electrodes 142 and 143 as the detection electrode. Alternatively, while the second and third beam-type oscillators are vibrating in the horizontal direction as the drive electrode, the vertical motions of the second and third beam-type electrodes 142 and 143 generated by the Coriolis force are detected by the first beam-type electrode 141 as the detection electrode. Specifically, the piezoelectric film 13 moves according to the voltage applied to the drive electrode, and the drive electrode vibrates in the drive direction. When the drive electrode is moved in the detection direction by the Coriolis force, the movement is converted into voltage by the piezoelectric film 13, and the detection electrode detects the converted voltage as the detection signal.

FIG. 12 shows an example of a circuit diagram of an angular velocity detecting device in which the first beam-type electrode 141 is vibrated in the vertical direction (in the stacking direction of the first beam-type electrode 141) and the second and third beam-type electrodes 142 and 143 detect horizontal movement of the first beam-type electrode 141 due to the Coriolis force. The control circuit 4 shown in FIG. 12 causes the drive electrode (the first beam-type electrode 141) of the oscillator 3 to vibrate at a predetermined drive vibration frequency and extracts the movement generated in the drive electrode by the Coriolis force through the detection electrode (the second and third beam-type electrodes 142 and 143) as voltage. The control circuit 4 includes the drive circuit 31, detection circuit 32, and detector circuit 33.

The drive circuit 31 is a circuit vibrating the first beam-type electrode 141 in the vertical direction. Specifically, the drive circuit 31 outputs to the first beam-type electrode 141 the drive signal to vibrate the first beam-type electrode 141 in the vertical direction.

The detection circuit 32 is a circuit detecting movement of the first beam-type electrode 141. Specifically, the detection circuit 32 receives a detected vibration signal generated as voltage by the second and third beam-type electrodes 142 and 143 according to the vibration of the first beam-type electrode 141.

The detector circuit 33 synchronously demodulates the detected vibration signal sent from the detection circuit 32 with the frequency of the drive vibration sent from the drive circuit 31 to output an angular velocity signal. The angular velocity signal is outputted through an output terminal OUT to the outside of the control circuit 4.

By integrally forming the oscillator 3 and control circuit 4 on the semiconductor substrate 2 into one chip, the angular velocity detecting device can be made smaller and thinner.

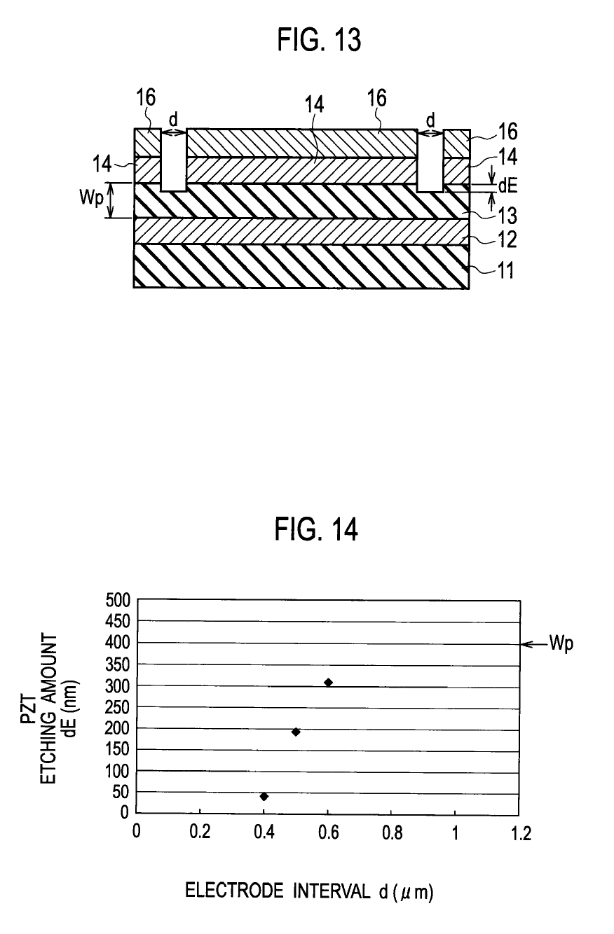

With reference to FIGS. 13 and 14, a description is given of an example of a method of providing the interval d12 between the first and second beam-type electrodes 141 and 142 and the interval d13 between the first and third beam-type electrodes 141 and 143 within the interval where the piezoelectric film 13 is not completely etched in the thickness direction by dry etching. An etching amount dE shown in FIG. 13 is an amount of a portion of the piezoelectric film 13 etched by dry etching after the upper electrode 14 is dry etched using the mask material 16 as a mask in the case where intervals of the mask material 16 are set to electrode interval d. Herein, the piezoelectric film 13 is a piezoelectric zirconate titanate (PZT) film with a thickness Wp of 400 nm.

FIG. 14 is a graph showing the electrode interval d in the horizontal axis and the etching amount dE in the vertical axis. As shown in FIG. 14, the wider the electrode interval d is, the larger the etching amount dE of the piezoelectric film 13 is. On the other hand, the narrower the electrode interval d is, the smaller the etching amount dE of the piezoelectric film 13 is, and etching stops in the middle of the piezoelectric film 13. As shown in FIG. 14, when the electrode interval d is not less than 8 μm, the etching amount dE is not less than 400 nm, and the piezoelectric film 13 is completely etched in the thickness direction from the upper surface to the bottom surface. The electrode interval d is set considering the thickness, material, and the like of the piezoelectric film 13 so that the first to third beam-type electrodes 141 to 143 are separated by dry etching and a part of the piezoelectric film 13 remains in each electrode interval to a thickness large enough to function as a piezoelectric element. For example, when the piezoelectric film 13 is a PZT film with a thickness of 400 nm, the intervals d12 and d13 are preferably about 0.3 to 0.5 μm and more preferably 0.4 μm.

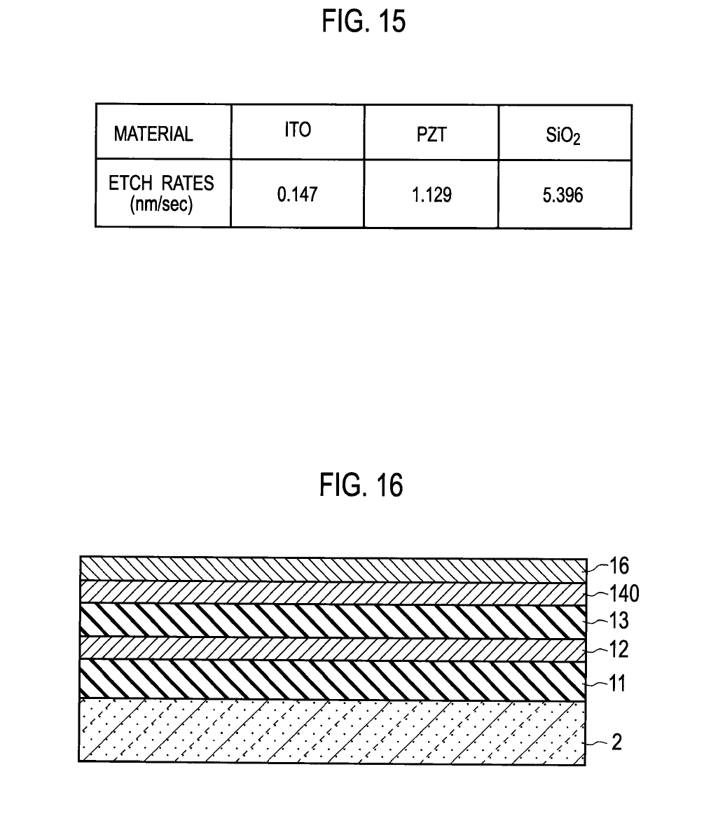

Next, the mask material 16 is described. The mask material 16 is preferably a material having an etching selectivity higher than the photoresist film with respect to the piezoelectric film 13 made of a PZT film or the like. Specifically, the mask material 16 can be an indium tin oxide (ITO) film, an alumina (Al₂O₃) film, or the like. Since alumina generally has a low deposition rate, ITO is preferred. FIG. 15 shows etch rates of dry etching of ITO, PZT, and silicon oxide (SiO₂). The conditions at the dry etching are those in the case of using fluorine and argon (Ar) gases.

Hereinafter, using FIGS. 16 to 24, a method of manufacturing the angular velocity detecting device according to the third embodiment of the present invention is described. The method of manufacturing the angular velocity detecting device according to the third embodiment of the present invention described below is an example. It is obvious that, in addition to this, various manufacturing methods including modifications thereof can be implemented.

(1) First, on the semiconductor substrate 2 composed of a silicon substrate or the like, for example, the lower protective film 11, the lower electrode 12, the piezoelectric film 13, an upper electrode film 140, and the mask material 16 are stacked in this order to obtain a structural cross-section shown in FIG. 16. The lower protective film 11 can be a SiO₂ film, for example. The lower electrode 12 can be a platinum (Pt) film with a thickness of about 200 nm formed by sputtering or the like. The piezoelectric film 13 can be a PZT film with a thickness of about 1 μm. The PZT film is formed by a sol-gel process or the like. The upper electrode film 140 can be an iridium oxide (IrO₂)/iridium (Ir) layered film with a thickness of about 200 nm formed by sputtering or the like. The mask material 16 can be made of ITO or the like.

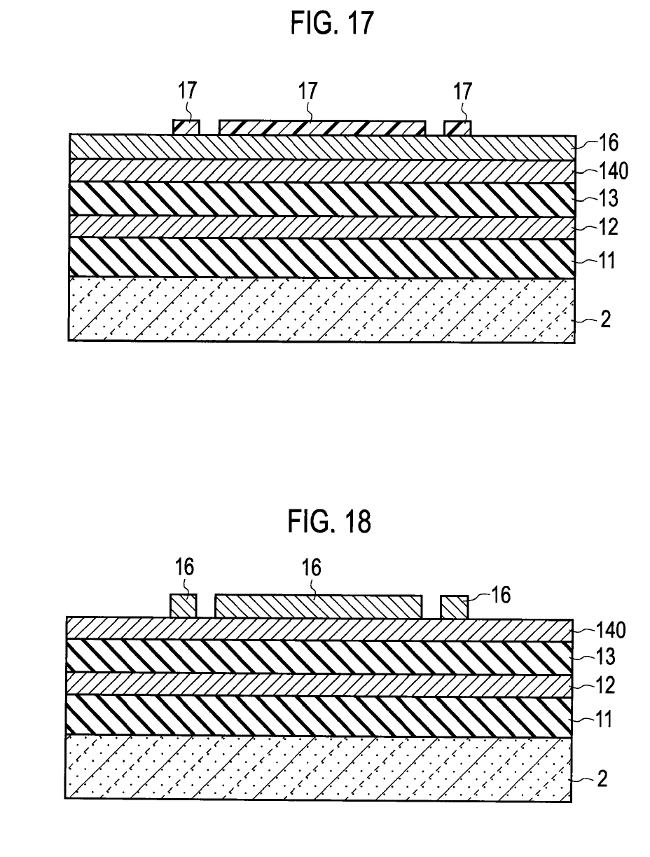

(2) Next, the photoresist film 17 is applied on the mask material 16, and as shown in FIG. 17, is patterned by photolithography into a desired power supply pattern. For example, the power supply pattern is formed so that the first beam-type electrode 141 with a width W1, the second beam-type electrode 142 with a width W2, and the third beam-type electrode 143 with a width W3, which are shown in FIG. 9, are formed at the intervals d12 and d13. At this time, the intervals d12 and d13 are set within the interval where the piezoelectric film 13 is not completely etched in the thickness direction by dry etching.

(3) Next, the mask material 16 is selectively removed by dry etching using the photoresist film 17 as a mask. For example, when the mask material 16 is made of an ITO film, the mask material 16 is etched using fluorine and Ar gases. The photoresist film 17 is then removed, thus obtaining the structural cross section shown in FIG. 18.

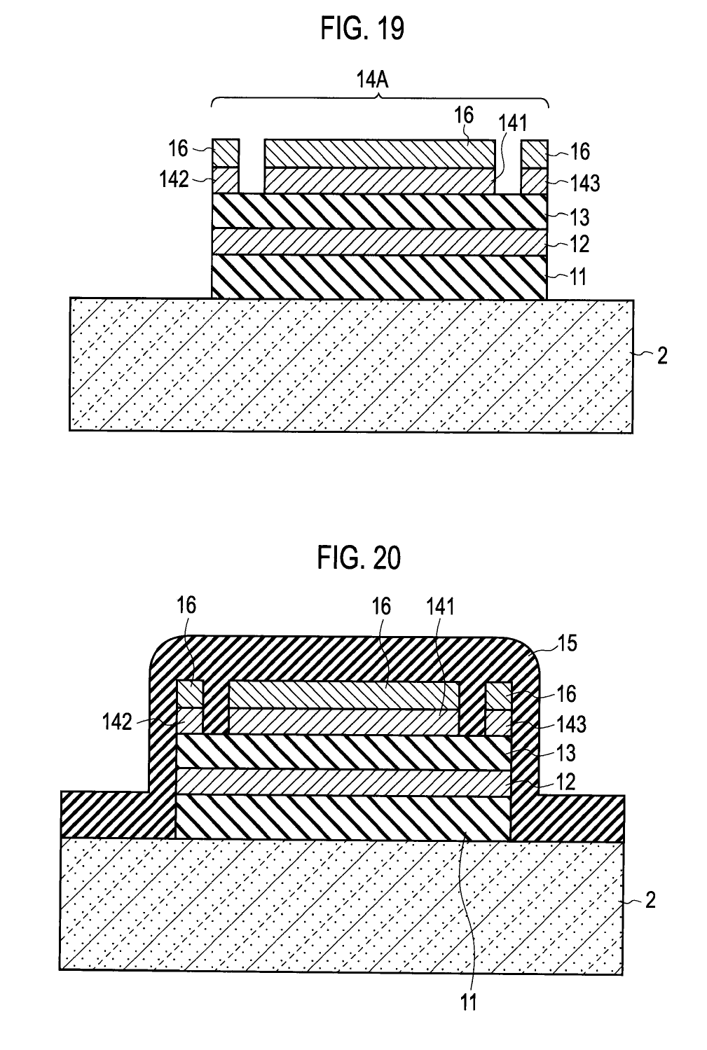

(4) Using the mask material 16 as a mask, part of an upper electrode film 140, piezoelectric film 13, lower electrode 12, and lower protective film 11 on the outside of the second and third beam-type electrodes 142 and 143, that is, the outside of the electrode area 14A. Simultaneously, part of the upper electrode film 140 between the first and second beam-type electrodes 141 and 142 and part thereof between the first and third beam-type electrodes 141 and 143 are etched. As a result, as shown in FIG. 19, the upper electrode film 140 is divided into the first to third beam-type electrodes 141 to 143. When the upper electrode film 140 is an IrO₂/Ir layered film, the upper electrode film 140 is etched by halogen gas such as chlorine (Cl₂) gas and Ar gas. When the piezoelectric film 13 is a PZT film, the piezoelectric film 13 is etched by fluorine and Ar gases. At this time, since the intervals d12 and d13 are narrower than the interval allowing the piezoelectric film 13 to be completely etched, part of the piezoelectric film 13 remains between the first and second beam-type electrodes 141 and 142 and between the first and third beam-type electrodes 141 and 143. When the lower electrode 12 is a Pt film, the lower electrode 12 is etched by halogen gas and Ar gas. When the lower protective film 11 is a SiO₂ film, the lower protective film 11 is etched by fluorine gas.

(5) The upper protective film 15 is formed on the entire surface of the oscillator 3 by sputtering or the like. The upper protective film 15 can be a SiO₂ film or the like. At this time, as shown in FIG. 20, the spaces between the first and second beam-type electrodes 141 and 142 and between the first and third beam-type electrodes 141 and 143 are filled with the upper protective film 15, and the upper protective film 15 is provided on the side surfaces of the first, second, and third beam-type electrodes 141 to 143. Moreover, the upper protective film 15 is formed on the side surfaces of the piezoelectric film 13 and lower electrode 12.

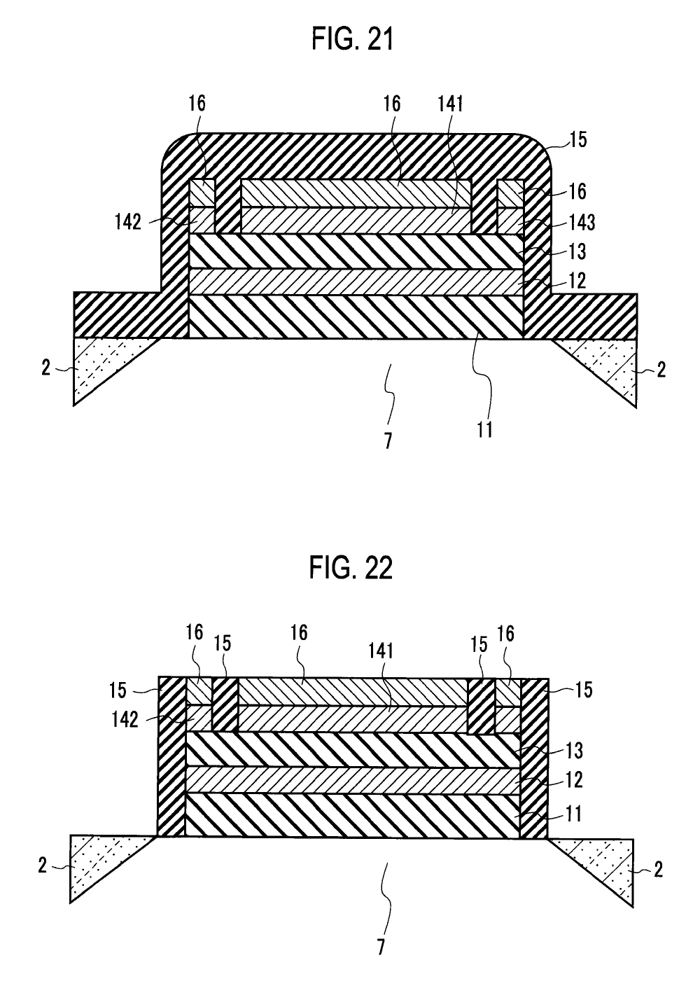

(6) The rear surface of the semiconductor substrate 2 is selectively etched by wet etching to form the cavity 7 under the oscillator 3 as shown in FIG. 21. At this time, the piezoelectric film 13 is prevented from being etched since the upper protective film 15 is formed on the side surfaces of the piezoelectric film 13.

(7) The upper protective film 15 is etched back to expose the upper surface of the mask material 16 and simultaneously expose the upper surface of the semiconductor substrate 2.

Another example of the method of selectively etching the rear surface of the semiconductor substrate 2 to form the cavity 7 is described below.

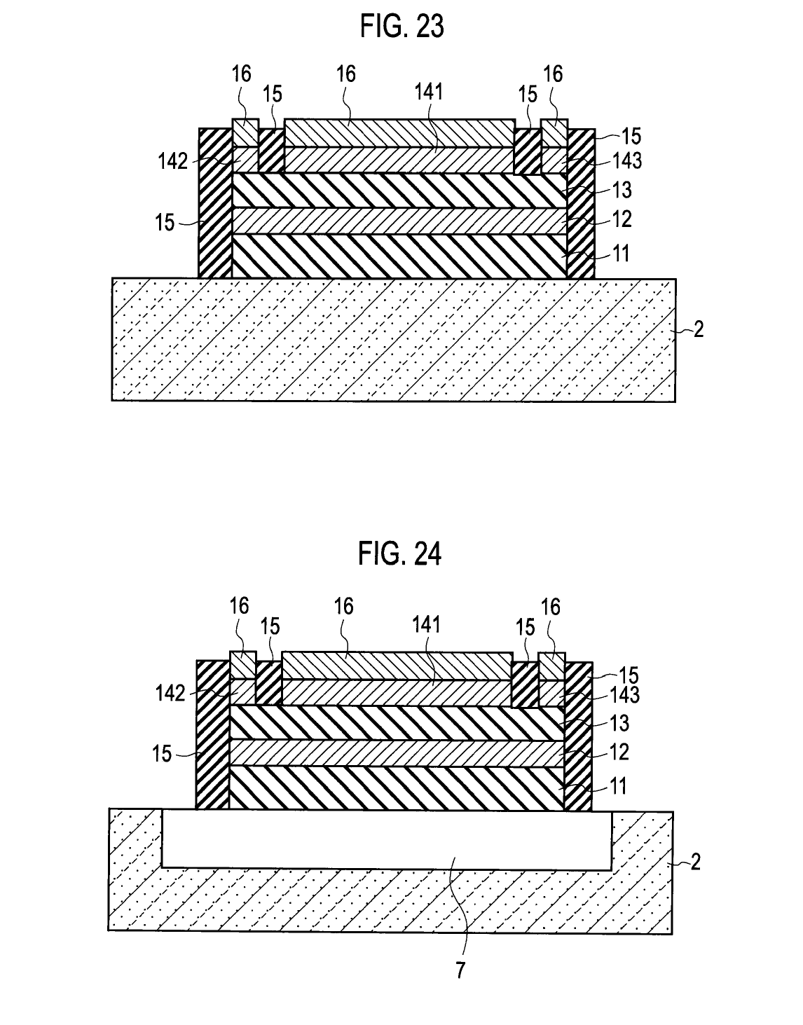

(1) After the structural cross-section shown in FIG. 20 is obtained, the upper protective film 15 is etched back to expose the upper surfaces of the mask material 16 and semiconductor substrate 2 as shown in FIG. 23.

(2) As shown in FIG. 24, part of the semiconductor substrate 2 is subjected to isotropic dry etching using fluorine gas to form the cavity 7 under the oscillator 3.

The angular velocity detecting device manufactured by the aforementioned example of the manufacturing method has a structure in which the mask material 16 is provided on the first to third beam-type electrodes 141 to 143. The mask material 16 may be removed to obtain the structure shown in FIGS. 9 to 11.

As described above, in the method of manufacturing the angular velocity detecting device according to the third embodiment of the present invention, the intervals d12 and d13 are provided within the interval where the piezoelectric film 13 is not completely etched in the thickness direction by dry etching. The first to third beam-type electrodes 141 to 143 are thus formed by one dry etching.

On the other hand, for etching each of the films constituting the oscillator 3, mask patterns for etching of each layer are prepared, and the first to third beam-type electrodes 141 to 143 are formed with the mask patterns being aligned. For example, in the case of an angular velocity detecting device of a large device size with a thickness of the oscillator 3 of not less than 100 μm, slight asymmetry of about 0.1 μm in the shape of the oscillator will not cause a problem of the accuracy in detecting the angular velocity. However, in the case of an angular velocity detecting device having a thickness of the oscillator 3 of about 10 μm, the output of the oscillator 3 is very small, and such slight asymmetry of about 0.1 μm in the shape of the oscillator due to misalignment of mask patterns or the like will cause abnormal vibration, thus degrading the accuracy in detecting the angular velocity.

For example, it is assumed that in the oscillator 3 shown in FIG. 9, the first beam-type electrode 141 is vibrated in the vertical direction (the drive direction) and movement of the first beam-type electrode 141 in the horizontal direction (the detection direction) due to the Coriolis force is detected by the second and third beam-type electrodes 142 and 143. Herein, when the lower protective film 11, lower electrode 12, piezoelectric film 13, and upper electrode 14 are formed with different etching masks, it is necessary to align each mask pattern. At this time, if misalignment of the mask patterns occurs and the horizontal distance between the end faces of the second electrode 142 and the lower protective film 11 is 0.9 μm and the horizontal distance between the end face of the second electrode 143 and the end face of the lower protective film 11 is 1.0 μm, abnormal vibration in the direction of vibration due to the Coriolis force (the detection direction) occurs before angular velocity is applied. Moreover, also when the distances between the center of the first beam-type electrode 141 and the right and left end faces of the lower protective film 11 differ by about 0.1 μm, abnormal vibration occurs. In other words, when the shape of the oscillator 3 has slight asymmetry of about 0.1 μm, abnormal vibration occurs, and minute changes due to the Coriolis force cannot be accurately detected.

However, as described above using FIGS. 16 to 24, in the method of manufacturing an angular velocity detecting device according to the third embodiment of the present invention, during the formation of the electrode area 14A of the oscillator 3, pattern formation by photolithography is carried out just one time, and there is no misalignment of mask patterns which will occurs in the case of using a plurality of etching masks. Accordingly, the shape of the oscillator 3 is not asymmetric, and the width W2 of the second beam-type electrode 142 and the width W3 of the third beam-type electrode 143 can be made equal to each other as designed. Moreover, the intervals d12 and d13 can be made equal to each other. The oscillator 3 can be symmetrically formed, thus preventing abnormal vibration due to the asymmetry of the shape of the oscillator 3. It is therefore possible to accurately detect minute changes due to the Coriolis force and detect the angular velocity at high accuracy.

### Other Embodiments

As described above, the present invention is described with the first to third embodiments, but it should not be understood that the present invention is limited by the description and drawings constituting part of the disclosure. From this disclosure, various substitutive embodiments, examples, and operational techniques will be apparent to those skilled in the art.

In the above description of the first to third embodiments, the oscillator 3 is a cantilever-type oscillator. However, the oscillator 3 may be an oscillator of a fixed-fixed beam structure with the drive and detection electrodes supported at the center. Moreover, the number of electrodes is three but certainly not limited to three.

As described above, it is obvious that the present invention includes various embodiments and the like not described here. Accordingly, the technical scope of the present invention is determined only by the features of the invention according to the claims proper from the aforementioned description.

### INDUSTRIAL APPLICABILITY

The angular velocity detecting device and the method of manufacturing the angular velocity detecting device of the present invention are applicable to electronics industries including manufacture manufacturing angular velocity detecting devices.

1. An angular velocity detecting device comprising:
a semiconductor substrate;
an oscillator on the semiconductor substrate; and
a control circuit configured to control the oscillator, the control circuit being on the semiconductor substrate.

2. The angular velocity detecting device of claim 1, wherein the oscillator includes a piezoelectric film inside.

3. The angular velocity detecting device of claim 1, wherein the oscillator is a beam type.

4. The angular velocity detecting device of claim 1 including a drive electrode and a detection electrode on the oscillator.

5. The angular velocity detecting device of claim 4, wherein the detection electrode is at a predetermined interval from the drive electrode.

6. The angular velocity detecting device of claim 5, wherein the predetermined interval is 0.3 to 0.5 μm.

7. The angular velocity detecting device of claim 1, wherein the control circuit comprises:
a drive circuit configured to output to the drive electrode a signal to vibrate the oscillator in a predetermined direction;
a detection circuit configured to detect a detection signal from a signal based on angular velocity of the oscillator which is provided from the detection electrode;
a detector circuit configured to detect the detection signal and provide an output signal.

8. The angular velocity detecting device of claim 2, wherein side surfaces of the piezoelectric film of the oscillator are covered with a protective film composed of an insulator.

9. The angular velocity detecting device of claim 8, wherein an upper or lower surface of the oscillator is covered with a protective film composed of an insulator.

10. The angular velocity detecting device of claim 9, wherein
the control circuit is covered with a protective film composed of an insulating film, and
at least a part of the protective film covering the oscillator is in continuity with the protective film covering the control circuit.

11. A method of manufacturing an angular velocity detecting device including an oscillator having a plurality of beam-type electrodes, the method comprising:
stacking a lower protective film, a lower electrode, a piezoelectric film, an upper electrode film, and a mask material on a semiconductor substrate;
patterning the mask material; and
etching the lower protective film, the lower electrode, the piezoelectric film, and the upper electrode film of the oscillator at a same time.

12. The method of manufacturing the angular velocity detecting device of claim 11, wherein the plurality of beam-type electrodes are provided at intervals of 0.3 to 0.5 μm.

13. The method of manufacturing the angular velocity detecting device of claim 11, wherein the piezoelectric film is a piezoelectric zirconate titanate (PZT) film.

14. The method of manufacturing the angular velocity detecting device of claim 11, wherein the mask material is an indium tin oxide (ITO) film.

15. The method of manufacturing the angular velocity detecting device of claim 11, further comprising:
removing a part of the semiconductor substrate under the plurality of beam-type electrodes.

16. The method of manufacturing the angular velocity detecting device of claim 11, further comprising:
forming a protective film on a side surface of the piezoelectric film.
